(19) United States
(12) Patent Application Publication
(10) Pub. No.: US 2025/0126930 A1
(43) Pub. Date: Apr. 17, 2025

(54) DISPLAY DEVICE AND METHOD FOR MANUFACTURING THE SAME

(71) Applicant: LG Display Co., Ltd., Seoul (KR)

(72) Inventors: Chunghwan AN, Goyang-si (KR); Jungeun SON, Goyang-si (KR); Hanyoung YANG, Goyang-si (KR); Jinho KIM, Paju-si (KR)

(73) Assignee: LG Display Co., Ltd., Seoul (KR)

(21) Appl. No.: 18/819,196

(22) Filed: Aug. 29, 2024

(30) Foreign Application Priority Data
Oct. 12, 2023 (KR) 10-2023-0136086

(51) Int. Cl. H01L 33/00; H01L 25/075

(52) U.S. Cl. CPC H10H 20/01; H01L 25/0753

(57) ABSTRACT

A display device may include a substrate on which pixels are defined, each pixel including a plurality of sub-pixels; a step formation layer disposed on the substrate; an adhesive layer disposed on the step formation layer; and a plurality of light-emitting elements respectively disposed in the plurality of sub-pixels, and disposed on the adhesive layer. The adhesive layer may include: a plurality of first portions respectively overlapping the light-emitting elements, a plurality of non-adhering areas respectively disposed adjacent to the plurality of first portions; and a second portion other than the plurality of first portions and the plurality of non-adhering areas. Accordingly, a transfer process may be simplified, and a transfer process time may be reduced. A method for manufacturing the display device is also disclosed.

### CROSS-REFERENCE TO RELATED APPLICATIONS

This application claims the benefit of and priority to Korean Patent Application No. 10-2023-0136086 filed on Oct. 12, 2023 in the Korean Intellectual Property Office, and all the benefits accruing therefrom under 35 U.S.C. 119. The entire contents of the foregoing application are incorporated herein by reference for all purposes.

### BACKGROUND

### 1. Technical Field

The present disclosure relates to a display device, and a method for manufacturing the display device, and more specifically, to a display device using an LED (Light Emitting Diode) and a method for manufacturing the display device.

### 2. Description of the Related Art

A display device used in computer monitors, TVs, cell phones, etc. includes an organic light-emitting display device (OLED) that emits light by itself, and a liquid crystal display device (LCD) that requires a separate light source, etc.

The scope of application of the display device is becoming more diverse, ranging from computer monitors and TVs to personal portable devices. Thus, research is being conducted on a display device that has a large display area size but reduced volume and weight.

Furthermore, recently, a display device including LED (Light Emitting Diode) as an inorganic light-emitting element is attracting attention as a next-generation display device. Since the LED is made of not an organic material but an inorganic material, the display device including the LED has excellent reliability and has a longer lifespan compared to the liquid crystal display device or the organic light-emitting display device. Furthermore, the LED not only has a fast turn on/off speed, but also has excellent light-emitting efficiency, strong impact resistance, excellent stability, and may display a high-brightness image.

The description of the related art should not be assumed to be prior art merely because it is mentioned in or associated with this section. The description of the related art includes information that describes one or more aspects of the subject technology, and the description in this section does not limit the invention.

### SUMMARY

In one or more aspects, a technical purpose that the present disclosure aims to achieve is to provide a display device and a method for manufacturing the display device in which only a portion of an adhesive layer to which a light-emitting element is to be transferred in a transfer process has an adhesive force, while the remaining portion thereof has no adhesive force.

In one or more aspects, another technical purpose that the present disclosure aims to achieve is to provide a display device and a method for manufacturing the display device in which an adhesion force of a portion of the adhesive layer corresponding to the light-emitting element is enhanced.

In one or more aspects, still another technical purpose that the present disclosure aims to achieve is to provide a display device and a method for manufacturing the display device in which some light-emitting elements among a plurality of light-emitting elements on a donor are selectively transferred to an area corresponding to a sub-pixel.

In one or more aspects, still yet another technical purpose that the present disclosure aims to achieve is to provide a display device and a method for manufacturing the display device in which a transfer process is simplified, and a transfer process time is reduced.

In one or more aspects, still yet another technical purpose that the present disclosure aims to achieve is to provide a display device and a method for manufacturing the display device in which a plurality of transfer processes may be consecutively performed using one donor.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

One aspect of the present disclosure provides a display device comprising: a substrate on which pixels are defined, each pixel including a plurality of sub-pixels; a step formation layer disposed on the substrate; an adhesive layer disposed on the step formation layer; and a plurality of light-emitting elements respectively disposed in the plurality of sub-pixels, and disposed on the adhesive layer, wherein the adhesive layer includes: a plurality of first portions respectively overlapping the plurality of light-emitting elements; a plurality of non-adhering areas respectively disposed adjacent to the plurality of first portions; and a second portion other than the plurality of first portions and the plurality of non-adhering areas.

Another aspect of the present disclosure provides a method for manufacturing a display device, wherein the method includes transferring a plurality of light-emitting elements on a wafer to a donor; disposing a step formation layer on a substrate of a display panel; patterning the step formation layer to form a first plurality of openings and a second plurality of openings defined in the step formation layer; disposing an adhesive layer on the step formation layer; disposing a mask on the adhesive layer and irradiating light to the adhesive layer; and transferring the plurality of light-emitting elements on the donor to the display panel, wherein the adhesive layer includes a plurality of first portions overlapping the mask, and a plurality of non-adhering areas not overlapping with the mask and subjected to the irradiated light, wherein each of the first plurality of openings overlaps with a respective one of the plurality of first portions, wherein each of the second plurality of openings overlaps with a respective one of the plurality of non-adhering areas, and wherein only light-emitting elements respectively in contact with the plurality of first portions among the plurality of light-emitting elements are transferred to the display panel.

Details of other embodiments are included in the detailed description and drawings.

The technical solutions according to the embodiment of the present disclosure are not limited to the solutions mentioned above, and other solutions not mentioned will be clearly understood by those skilled in the art from the description below.

In accordance with the display device and the method for manufacturing the display device according to the present disclosure, only a portion of an adhesive layer to which a light-emitting element is to be transferred in a transfer process has an adhesive force, while the remaining portion thereof has no adhesive force.

In accordance with the display device and the method for manufacturing the display device according to one or more example embodiments of the present disclosure, an adhesion force of a portion of the adhesive layer corresponding to the light-emitting element is enhanced.

In accordance with the display device and the method for manufacturing the display device according to one or more example embodiments of the present disclosure, some light-emitting elements among a plurality of light-emitting elements on a donor are selectively transferred to an area corresponding to a sub-pixel.

In accordance with the display device and the method for manufacturing the display device according to one or more example embodiments of the present disclosure, a transfer process is simplified, and a transfer process time is reduced.

In accordance with the display device and the method for manufacturing the display device according to one or more example embodiments of the present disclosure, a plurality of transfer processes may be consecutively performed using one donor.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a schematic diagram of a display device according to one example embodiment of the present disclosure.

FIG. 2A is a cross-sectional view of a portion of a display device according to one example embodiment of the present disclosure.

FIG. 2B is a perspective view of a tiling display apparatus according to one example embodiment of the present disclosure.

FIG. 3A is an enlarged plan view of a display device according to one example embodiment of the present disclosure.

FIG. 3B is a cross-sectional view of a display device according to one example embodiment of the present disclosure.

FIGS. 4A to 4I illustrate a method for manufacturing a display device according to one example embodiment of the present disclosure.

FIGS. 5A to 5E illustrate a method for manufacturing a display device according to one example embodiment of the present disclosure.

FIG. 6 is a cross-sectional view of a display device according to another example embodiment of the present disclosure.

FIG. 7A is a top view of a display device according to another example embodiment of the present disclosure.

FIG. 7B is an example of a cross-sectional view of an area A-A′ in FIG. 7A.

FIG. 7C is an example of a cross-sectional view of an area B-B′ in FIG. 7A.

FIG. 8 is a top view of a display device according to still another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be embodied in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. In one or more examples, an element may include one or more elements. In one or more examples, an element may include a plurality of elements. It will be further understood that the terms “comprise”, “comprising”, “have,” having,” “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be embodied differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be embodied independently of each other and may be embodied together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase “immediately transferred” or “directly transferred” is used.

Hereinafter, the present disclosure will be described with reference to the drawings.

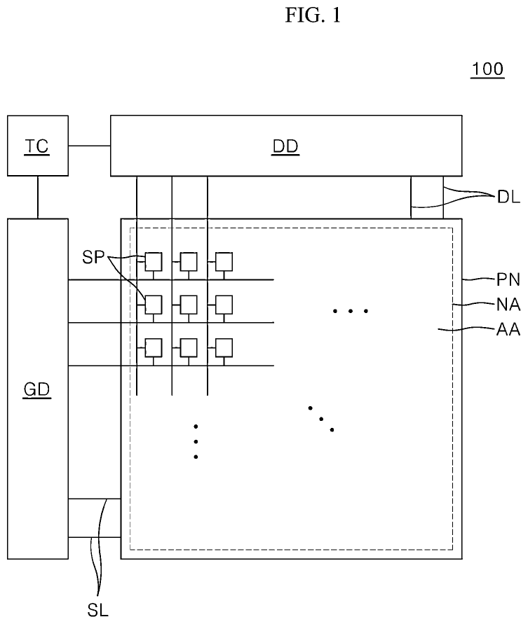

FIG. 1 is a schematic diagram of a display device according to one example embodiment of the present disclosure. For convenience of illustration, FIG. 1 shows only a display panel PN, a gate driver GD, a data driver DD, and a timing controller TC among various components of the display device 100.

Referring to FIG. 1, the display device 100 includes the display panel PN including a plurality of sub-pixels SP, the gate driver GD and the data driver DD that supply various signals to the display panel PN, and a timing controller TC that controls the gate driver GD and the data driver DD.

The gate driver GD supplies a plurality of scan signals to a plurality of scan lines SL according to a plurality of gate control signals provided from the timing controller TC. In FIG. 1, one gate driver GD is shown as being disposed on and spaced apart from one side of the display panel PN. However, the number and arrangement of gate drivers GD are not limited thereto.

The data driver DD converts image data input from the timing controller TC into a data voltage using a reference gamma voltage according to a plurality of data control signals provided from the timing controller TC. The data driver DD may supply the converted data voltage to a plurality of data lines DL.

The timing controller TC aligns the image data input from an external source and supplies the aligned data to the data driver DD. The timing controller TC may generate a gate control signal and a data control signal using a synchronization signal input from an external source, for example, a dot clock signal, a data enable signal, and a horizontal/vertical synchronization signal. The timing controller TC may supply the generated gate control signal and the generated data control signal to the gate driver GD and the data driver DD, respectively to control the gate driver GD and the data driver DD.

The display panel PN is a component for displaying an image to a user, and includes the plurality of sub-pixels SP. In the display panel PN, the plurality of scan lines SL and the plurality of data lines DL intersect each other, and each of the plurality of sub-pixels SP is connected to the scan line SL and the data line DL. Although not shown in the figure, each of the plurality of sub-pixels SP may be connected to a high-potential power line, a low-potential power line, a reference voltage line, etc.

A display area AA and a non-display area NA surrounding the display area AA may be defined in the display panel PN.

The display area AA is an area where an image is displayed in the display device 100. A plurality of sub-pixels SP constituting each of a plurality of pixels PX and a circuit for driving the plurality of sub-pixels SP may be disposed in the display area AA. Each of the plurality of sub-pixels SP refers to a minimum unit that constitutes the display area AA, and n sub-pixels SP may constitute one pixel PX. A light-emitting element and a thin-film transistor for driving the light-emitting element may be disposed in each of the plurality of sub-pixels SP. A type of a plurality of light-emitting elements may vary depending on a type of the display panel PN. For example, when the display panel PN is an inorganic light-emitting display panel, the light-emitting element 120 may be a light-emitting diode (LED) or a micro light-emitting diode (micro LED).

In the display area AA, a plurality of signal lines that transmits various signals to the plurality of sub-pixels SP is disposed. For example, the plurality of signal lines may include the plurality of data lines DL which supply the data voltage to each of the plurality of sub-pixels SP, and the plurality of scan lines SL that supply the gate voltage to each of the plurality of sub-pixels SP, etc. The plurality of scan lines SL may extend in one direction in the display area AA and may be connected to the plurality of sub-pixels SP, and the plurality of data lines DL may extend in a direction different from the one direction in the display area AA, and may be connected to the plurality of sub-pixels SP. In addition, the low-potential power line, the high-potential power line, etc. may be further disposed in the display area AA. However, embodiments of the present disclosure are not limited thereto.

The non-display area NA is an area where an image is not displayed and may be defined as an area extending from the display area AA. In the non-display area NA, a link line and a pad electrode to transmit signals to the sub-pixel SP of the display area AA, or driver ICs such as a gate driver IC and a data driver IC may be disposed.

In one example, the non-display area NA may be located on a back surface of the display panel PN, that is, on a surface thereof in which the sub-pixels SP are absent, or may be omitted. However, the present disclosure is not limited to what is shown in the drawing.

In one example, the drivers such as the gate driver GD, the data driver DD, and the timing controller TC may be connected to the display panel PN in various schemes. For example, the gate driver GD may be mounted in a GIP (Gate In Panel) scheme in the non-display area NA, or may be installed between the plurality of sub-pixels SP in the display area AA in a GIA (Gate In Active Area) scheme. For example, the data driver DD and the timing controller TC may be formed in a separate flexible film and printed circuit board, and the flexible film and the printed circuit board may be bonded to the pad electrode formed in the non-display area NA of the display panel PN and thus the data driver DD and the timing controller TC may be electrically connected to the display panel PN. When the gate driver GD is implemented in the GIP scheme and the data driver DD and the timing controller TC transmit the signals to the display panel PN via the pad electrode in the non-display area NA, it is necessary to secure an area of the non-display area NA in which the gate driver GD and the pad electrode are disposed, such that a bezel size may increase.

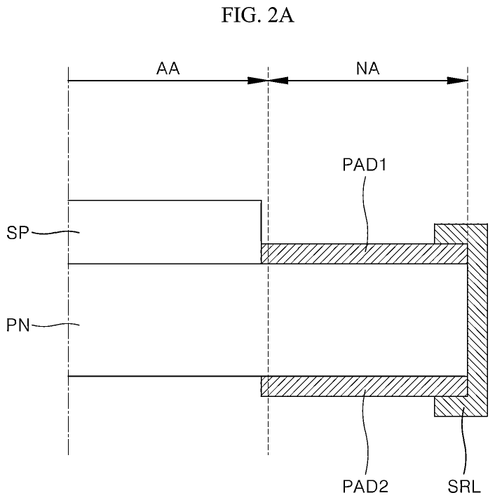

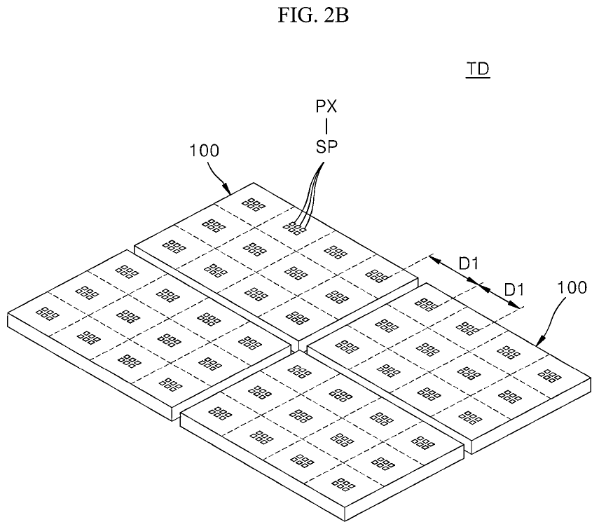

Alternatively, the gate driver GD may be mounted in the display area AA using the GIA scheme, and a side line SRL connecting a signal line of a front surface of the display panel PN to the pad electrode of a back surface of the display panel PN may be formed, and the flexible film and the printed circuit board are bonded to the back surface of the display panel PN. In this case, a size of the non-display area NA of the front surface of the display panel PN may be reduced to a minimum size. In other words, when the gate driver GD, the data driver DD, and the timing controller TC are connected to the display panel PN using the above scheme, this may implement a zero bezel in which a bezel is substantially absent. Descriptions thereof refer to FIG. 2A and FIG. 2B.

FIG. 2A is a cross-sectional view of a portion of a display device according to one example embodiment of the present disclosure. FIG. 2B is a perspective view of a tiling display apparatus according to one example embodiment of the present disclosure.

A plurality of pad electrodes are disposed in the non-display area NA of the display panel PN to transmit various signals to a plurality of sub-pixels SP. For example, a first pad electrode PAD1 which transmits signals to the plurality of sub-pixels SP may be disposed in the non-display area NA of the front surface of the display panel PN. A second pad electrode PAD2 may be disposed in the non-display area NA of the back surface of the display panel PN and may be electrically connected to driving components such as the flexible film and the printed circuit board.

In this case, although not shown in the drawing, various signal lines connected to the plurality of sub-pixels SP, for example, the scan line SL or the data line DL may extend from the non-display area NA to the display area AA and may be electrically connected to the first pad electrode PAD1.

A side line SRL is disposed along a side surface of the display panel PN. The side line SRL may electrically connect the first pad electrode PAD1 of the front surface of the display panel PN and the second pad electrode PAD2 of the back surface of the display panel PN to each other. Accordingly, signals from the driving components of the back surface of the display panel PN may be transmitted to the plurality of sub-pixels SP through the second pad electrode PAD2, the side line SRL, and the first pad electrode PAD1. Therefore, an area size of the non-display area NA of the display panel PN may be minimized by forming a signal transmission path from the front surface to the side surface to the back surface of the display panel PN.

Further, referring to FIG. 2B, a tiling display apparatus TD with a large screen may be implemented by connecting a plurality of display devices 100 to each other. In this regard, as shown in FIG. 2A, when the tiling display apparatus TD is implemented using the display devices 100 having a minimized bezel, a seam area between adjacent display devices 100 in which an image is not displayed may be minimized such that display quality may be improved.

For example, the plurality of sub-pixels SP may constitute one pixel PX, and a spacing D1 between the outermost pixel PX of one display device 100 and the outermost pixel PX of another display device 100 adjacent thereto may be equal to a spacing D1 between adjacent pixels PX within one display device 100. Accordingly, the spacings between the pixels PX of adjacent display devices 100 and the spacings between the pixels PX in the display device 100 may be constant, thereby minimizing the seam area.

However, FIG. 2A and FIG. 2B are merely examples, and the display device 100 according to one example embodiment of the present disclosure may be a general display device with a bezel. However, embodiments of the present disclosure are not limited thereto.

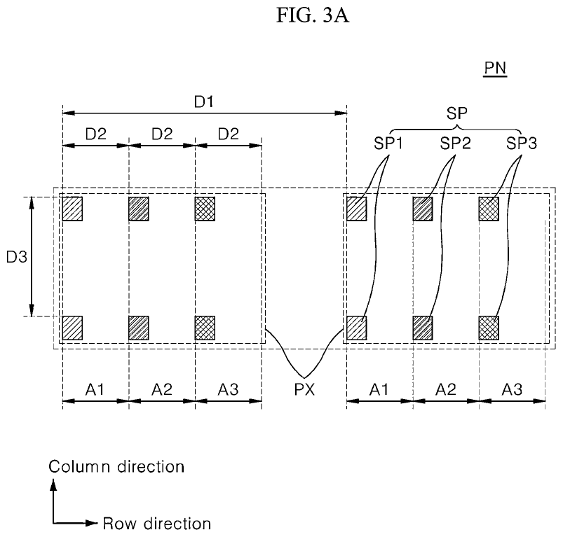

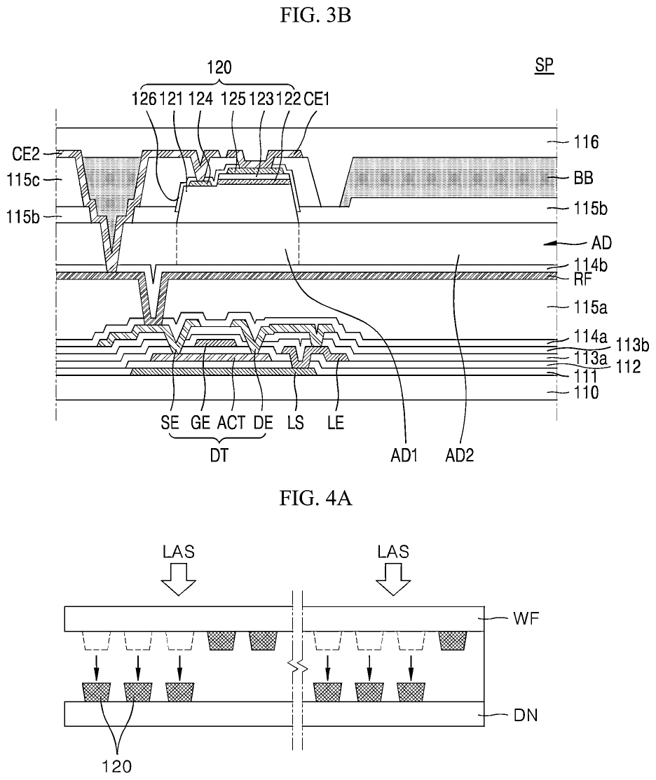

FIG. 3A is an enlarged plan view of a display device according to one example embodiment of the present disclosure. FIG. 3B is a cross-sectional view of a display device according to one example embodiment of the present disclosure.

First, referring to FIG. 3A, the display panel PN includes the plurality of pixels PX, each including the plurality of sub-pixels SP. Each of the plurality of sub-pixels SP may include a light-emitting element and a pixel circuit and thus emit light independently. For example, a first sub-pixel SP1 may be a red sub-pixel, a second sub-pixel SP2 may be a green sub-pixel, and a third sub-pixel SP3 may be a blue sub-pixel. However, embodiments of the present disclosure are not limited thereto.

One pixel PX may include one or more first sub-pixels SP1, one or more second sub-pixels SP2, and one or more third sub-pixels SP3. For example, one pixel PX may be composed of two first sub-pixels SP1, two second sub-pixels SP2, and two third sub-pixels SP3.

Hereinafter, an example in which one pixel PX includes a pair of first sub-pixels SP1, a pair of second sub-pixels SP2, and a pair of third sub-pixels SP3 is described. However, a configuration of the pixel PX is not limited thereto.

The plurality of sub-pixels SP included in one pixel PX may be arranged in a pair of rows. For example, in a first row, one first sub-pixel SP1, one second sub-pixel SP2, and one third sub-pixel SP3 may be sequentially arranged. In a second row, the remaining first sub-pixel SP1, the remaining second sub-pixel SP2, and the remaining third sub-pixel SP3 may be sequentially arranged.

Only one type of sub-pixels SP may be arranged in one column. For example, in one pixel PX, only the first sub-pixel SP1 may be disposed in a first column, only the second sub-pixel SP2 may be disposed in a second column, and only the third sub-pixel SP3 may be disposed in a third column. An area corresponding to the column where the first sub-pixel SP1 is disposed may be defined as a first area A1, an area corresponding to the column where the second sub-pixel SP2 is disposed may be defined as a second area A2, and an area corresponding to the column where the third sub-pixel SP3 is disposed may be defined as a third area A3.

The plurality of pixels PX may be arranged so as to be spaced from each other by an equal spacing in the row direction. For example, in the row direction, the plurality of pixels PX be arranged so as to be spaced from each other by an equal spacing equal to a first length D1. That is, a pitch of the pixel PX may be the first length D1. Furthermore, although not shown in the drawing, the plurality of pixels PX may be arranged so as to be spaced from each other by an equal spacing in the column direction.

The sub-pixels SP arranged in the same row in one pixel PX may be arranged so as to be spaced from each other by an equal spacing. For example, the sub-pixels SP arranged in the same row in one pixel PX may be arranged so as to be spaced from each other by an equal spacing equal to a second length D2. In other words, a width of each of a plurality of first areas A1, each of a plurality of second areas A2, and each of a plurality of third areas A3 may be the second length D2. Additionally, the sub-pixels SP arranged in the same column in one pixel PX may be arranged so as to be spaced from each other by an equal spacing equal to a third length D3.

Next, referring to FIG. 3B, each of the plurality of sub-pixels SP of the display panel PN of the display device 100 according to one example embodiment of the present disclosure may include a substrate 110, a buffer layer 111, a gate insulating layer 112, a first interlayer insulating layer 113a, a second interlayer insulating layer 113b, a first passivation layer 114a, a first planarization layer 115a, a second passivation layer 114b, an adhesive layer AD, a second planarization layer 115b, a third planarization layer 115c, a protective layer 116, a bank BB, a driving transistor DT, a light-emitting element 120, a reflective layer RF, a first connection electrode CE1, a second connection electrode CE2, a light blocking layer LS, and an auxiliary electrode LE.

First, the substrate 110 is a component for supporting various components included in the display device 100 and may be made of an insulating material. For example, the substrate 110 may be made of glass or resin. Further, the substrate 110 may be made of polymers or plastic, and may be made of a material with flexibility.

The light-blocking layer LS is disposed on the substrate 110 in each of the plurality of sub-pixels SP. The light-blocking layer LS prevents light incident from a position under the substrate 110 from invading the active layer ACT of the driving transistor DT, which will be described later. the light-blocking layer LS may prevent the light from being incident to the active layer ACT of the driving transistor DT, thereby minimizing leakage current.

The buffer layer 111 is disposed on the substrate 110 and the light-blocking layer LS. The buffer layer 111 may reduce the permeation of moisture or impurities through the substrate 110. The buffer layer 111 may be composed of, for example, a single layer or a multi-layer made of silicon oxide (SiOₓ) or silicon nitride (SiNₓ). However, the present disclosure is not limited thereto. However, the buffer layer 111 may be omitted depending on a type of the substrate 110 or a type of the transistor. However, the present disclosure is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be made of a semiconductor material such as oxide semiconductor, amorphous silicon, or polysilicon. However, the present disclosure is not limited thereto.

The gate insulating layer 112 is disposed on the active layer ACT. The gate insulating layer 112 is an insulating layer for insulating the active layer ACT and the gate electrode GE from each other, and may be composed of a single layer or a multi-layer made of silicon oxide (SiOx) or silicon nitride (SiNx). However, the present disclosure is not limited thereto.

The gate electrode GE is disposed on the gate insulating layer 112. The gate electrode GE may be made of a conductive material such as copper (Cu), aluminum (Al), molybdenum (Mo), nickel (Ni), titanium (Ti), chromium (Cr), or an alloy thereof. However, the present disclosure is not limited thereto.

The first interlayer insulating layer 113a and the second interlayer insulating layer 113b are disposed on the gate electrode GE. The first interlayer insulating layer 113a and the second interlayer insulating layer 113b have contact-holes defined therein for respectively connecting the source electrode SE and the drain electrode DE to the active layer ACT. Each of the first interlayer insulating layer 113a and the second interlayer insulating layer 113b acts as an insulating layer for protecting components under the first interlayer insulating layer 113a and the second interlayer insulating layer 113b, and may be composed of a single layer or double layers made of silicon oxide (SiOx) or silicon nitride (SiNx). However, the present disclosure is not limited thereto.

The source electrode SE and the drain electrode DE electrically connected to the active layer ACT are disposed on the second interlayer insulating layer 113b. Each of the source electrode SE and the drain electrode DE may be made of a conductive material such as copper (Cu), aluminum (Al), molybdenum (Mo), nickel (Ni), titanium (Ti), chromium (Cr), or an alloy thereof. However, the present disclosure is not limited thereto.

In one example, the present disclosure describes an example in which the first interlayer insulating layer 113a and the second interlayer insulating layer 113b, that is, a plurality of insulating layers are disposed between the gate electrode GE and the source electrode SE, and the drain electrode DE. However, the present disclosure is not limited thereto. Only one insulating layer may be disposed between the gate electrode GE and the source electrode SE, and the drain electrode DE.

Further, when, as shown in the drawing, the plurality of insulating layers such as the first interlayer insulating layer 113a and the second interlayer insulating layer 113b are disposed between the gate electrode GE and the source electrode SE, and the drain electrode DE, an electrode may be additionally formed between the first interlayer insulating layer 113a and the second interlayer insulating layer 113b. The additionally formed electrode and another component disposed under the first interlayer insulating layer 113a or on top of the second interlayer insulating layer 113b may constitute a capacitor.

The auxiliary electrode LE is disposed on the gate insulating layer 112. The auxiliary electrode LE acts as an electrode that electrically connects the light-blocking layer LS disposed under the buffer layer 111 to one of the source electrode SE and the drain electrode DE disposed on the second interlayer insulating layer 113b. For example, since the light-blocking layer LS is electrically connected to either the source electrode SE or the drain electrode DE via the auxiliary electrode LE and does not operate as a floating gate, change in a threshold voltage of the driving transistor DT otherwise caused by the floating light-blocking layer LS may be minimized. In the drawing, the light-blocking layer LS is shown as being connected to the drain electrode DE. However, the present disclosure is not limited thereto. The light-blocking layer LS may be connected to the source electrode SE.

The first passivation layer 114a is disposed on the driving transistor DT. The first passivation layer 114a may be an insulating layer to protect a structure under the first passivation layer 114a, and may be composed of a single layer or multiple layers made of silicon oxide (SiOₓ) or silicon nitride (SiNₓ). However, the present disclosure is not limited thereto.

The first planarization layer 115a is disposed on the first passivation layer 114a. The first planarization layer 115a may planarize a top of a portion of the substrate 110 in which the driving transistor DT is disposed. The first planarization layer 115a may be composed of a single layer or a multiple layer made of, for example, photoresist or an acryl-based organic material. However, embodiments of the present disclosure are not limited thereto.

The reflective layer RF is disposed on the first planarization layer 115a. The reflective layer RF may electrically connect the light-emitting element 120 to the driving transistor DT and may reflect the light-emitted from the light-emitting element 120 therefrom so as to be directed upwardly of the light-emitting element 120. The reflective layer RF may be made of a conductive material with excellent reflective properties and may reflect light-emitted from the light-emitting element 120 therefrom so as to be directed upwardly of the light-emitting element.

The second passivation layer 114b is disposed on the reflective layer RF. The second passivation layer 114b may be an insulating layer to protect the structure under the second passivation layer 114b, and may be composed of a single layer or multiple layers made of silicon oxide (SiOₓ) or silicon nitride (SiNₓ). However, embodiments of the present disclosure are not limited thereto.

The adhesive layer AD is disposed on the second passivation layer 114b. The adhesive layer AD may be coated on an entire surface of the substrate 110 to fix the light-emitting element 120 disposed on the adhesive layer AD to the substrate. The adhesive layer AD may be made of a photocurable adhesive material that may be curable by light. For example, the adhesive layer AD may be made of an acrylic-based material containing a photosensitive agent. However, embodiments of the present disclosure are not limited thereto. The adhesive layer AD may be formed across an entire surface of the display panel PN excluding an area where the pad electrode is to be disposed. For example, as shown in FIG. 2A, when the plurality of first pad electrodes PAD1 are formed on the front surface of the display panel PN, the adhesive layer AD may be formed in the remaining area other than the area where the first pad electrode PAD1 is formed.

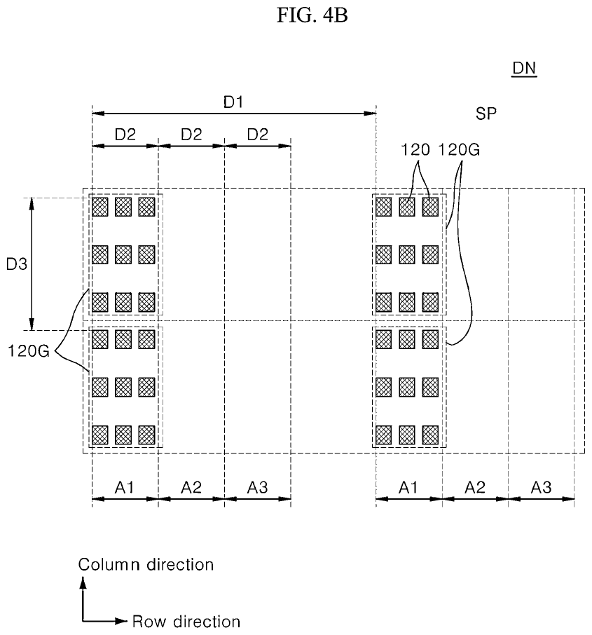

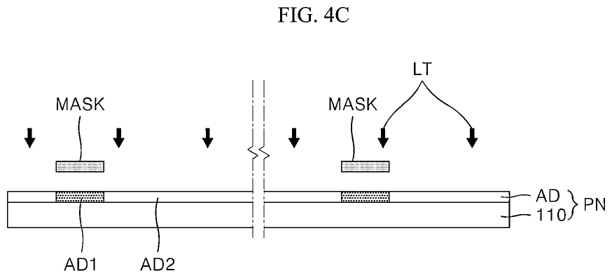

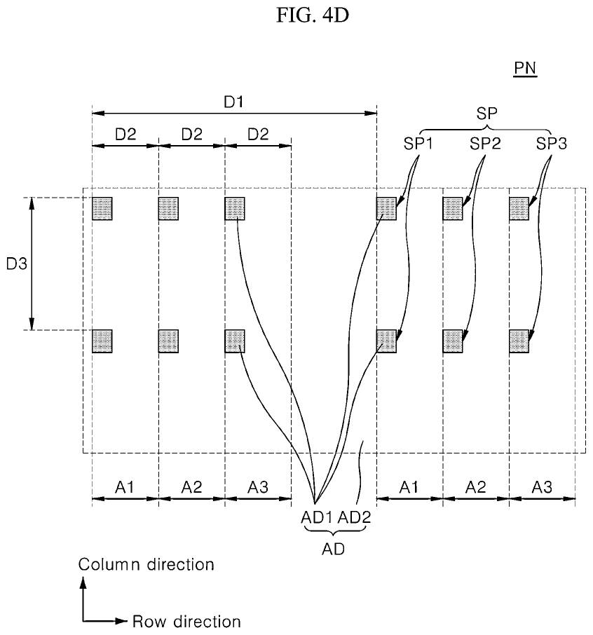

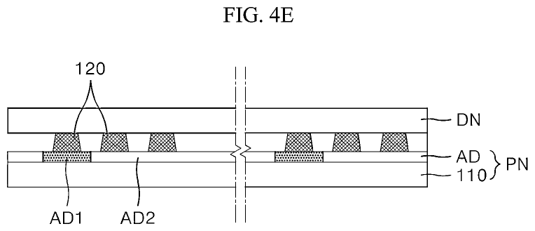

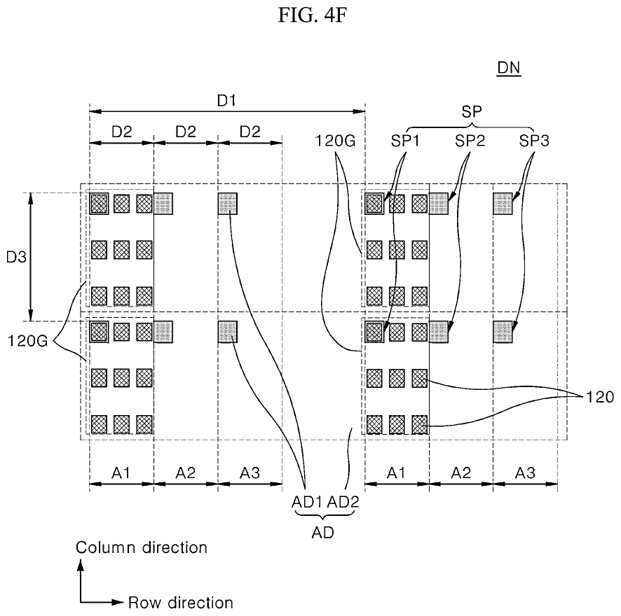

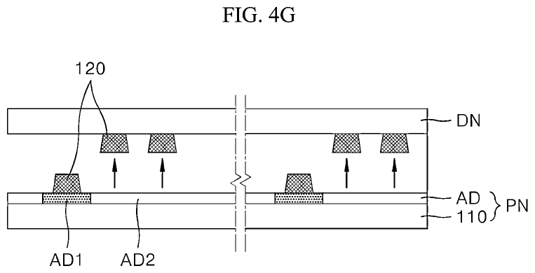

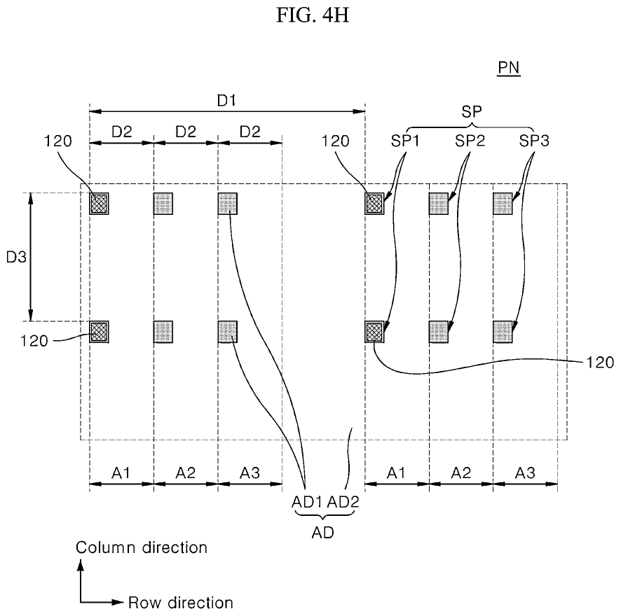

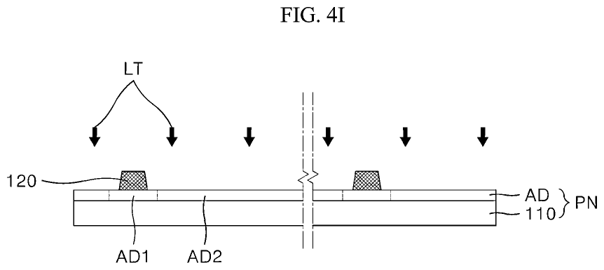

The adhesive layer AD may be composed of a plurality of first portions AD1 that overlap a plurality of light-emitting elements 120, respectively, and a second portion AD2 as the remaining portion excluding the plurality of first portions AD1. The second portion AD2 of the adhesive layer AD may be cured before the light-emitting element 120 is transferred to the display panel PN, and the plurality of first portions AD1 of the adhesive layer AD may be cured after the light-emitting element 120 is transferred to the display panel PN. The plurality of first portions AD1 and the second portion AD2 of the adhesive layer AD may be cured at different timings, such that only a light-emitting element 120 that overlaps the plurality of sub-pixels SP among the plurality of light-emitting elements 120 disposed on a donor may be selectively transferred to the display panel PN. A more detailed description thereof will be described later with reference to FIG. 4A to FIG. 4I.

The plurality of light-emitting elements 120 are disposed in each of the plurality of sub-pixels SP and on the adhesive layer AD. The plurality of light-emitting elements 120 may refer to an element that emits light based on electric current, and may include light-emitting elements 120 that emit red light, green light, blue light, etc., respectively, and may emits light of a combination thereof to produce white light. For example, each of the plurality of light-emitting elements 120 may be embodied as a LED (Light Emitting Diode) or (micro LED). However, embodiments of the present disclosure are not limited thereto.

The light-emitting element 120 includes a first semiconductor layer 121, a light-emitting layer 122, a second semiconductor layer 123, a first electrode 124, a second electrode 125, and an encapsulation film 126.

The first semiconductor layer 121 is disposed on the adhesive layer AD, and the second semiconductor layer 123 is disposed on the first semiconductor layer 121. The first semiconductor layer 121 and the second semiconductor layer 123 may be formed by doping n-type and p-type impurities into a specific material, respectively. For example, the first semiconductor layer 121 and the second semiconductor layer 123 may respectively contain doped n-type and p-type impurities in a matrix made of gallium nitride (GaN), indium aluminum phosphide (InAlP), or gallium arsenide (GaAs). In this regard, the p-type impurity may be magnesium (Mg), zinc (Zn), beryllium (Be), etc., and the n-type impurity may be silicon (Si), germanium (Ge), tin (Sn), etc. However, embodiments of the present disclosure are not limited thereto.

The light-emitting layer 122 is disposed between the first semiconductor layer 121 and the second semiconductor layer 123. The light-emitting layer 122 may emit light upon receiving holes and electrons from the first semiconductor layer 121 and the second semiconductor layer 123, respectively. The light-emitting layer 122 may be made of a single-layer or a multi-quantum well (MQW) structure, and may be made of, for example, indium gallium nitride (InGaN) or gallium nitride (GaN). However, embodiments of the present disclosure are not limited thereto.

The first electrode 124 is disposed on the first semiconductor layer 121. The first electrode 124 is an electrode for electrically connecting the driving transistor DT and the first semiconductor layer 121 to each other. The first electrode 124 may be disposed on a portion of an upper surface of the first semiconductor layer 121 not covered with the light-emitting layer 122 and the second semiconductor layer 123. The first electrode 124 may be made of a conductive material, for example, a transparent conductive material such as ITO (Indium Tin Oxide) or IZO (Indium Zinc Oxide), or an opaque conductive material such as titanium (Ti), gold (Au), silver (Ag), copper (Cu), or an alloy thereof. However, embodiments of the present disclosure are not limited thereto.

The second electrode 125 is disposed on the second semiconductor layer 123. The second electrode 125 may be disposed on an upper surface of the second semiconductor layer 123. The second electrode 125 is an electrode for electrically connecting a power line and the second semiconductor layer 123 to each other. The second electrode 125 may be made of a conductive material, for example, a transparent conductive material such as ITO (Indium Tin Oxide) or IZO (Indium Zinc Oxide), or an opaque conductive material such as titanium (Ti), gold (Au), silver (Ag), copper (Cu), or an alloy thereof. However, embodiments of the present disclosure are not limited thereto.

Next, the encapsulation film 126 surrounding the first semiconductor layer 121, the light-emitting layer 122, the second semiconductor layer 123, the first electrode 124, and the second electrode 125 is disposed. The encapsulation film 126 may be made of an insulating material and may protect the first semiconductor layer 121, the light-emitting layer 122, and the second semiconductor layer 123. Further, a contact hole exposing the first electrode 124 and the second electrode 125 may be formed in the encapsulation film 126, such that the first connection electrode CE1, the second connection electrode CE2, and the first electrode 124 and the second electrode 125 may be electrically connected to each other via the contact hole.

In one example, a portion of a side surface of the first semiconductor layer 121 may be not covered with the encapsulation film 126. The light-emitting element 120 manufactured on the wafer may be removed from the wafer and transferred to the display panel PN. However, in a process of removing the light-emitting element 120 from the wafer, a portion of the encapsulation film 126 may be torn. For example, a portion of the encapsulation film 126 adjacent to a lower edge of the first semiconductor layer 121 of the light-emitting element 120 may be torn off during the removal process of the light-emitting element 120 from the wafer such that a portion of a lower side surface of the semiconductor layer 121 may be exposed to an outside. However, even when the portion of the lower side surface of the light-emitting element 120 is not covered with the encapsulation film 126, the second planarization layer 115b and the third planarization layer 115c may be formed so as to cover the side surface of the first semiconductor layer 121 and then, the first connection electrode CE1 and the second connection electrode CE2 may be formed, such that a short circuit defect may be reduced.

Next, the second planarization layer 115b and the third planarization layer 115c are sequentially disposed on the adhesive layer AD and the light-emitting element 120. The second planarization layer 115b may overlap a portion of a side surface of each of the plurality of light-emitting elements 120 and may fix and protect the plurality of light-emitting elements 120. The third planarization layer 115c may be formed to cover the second planarization layer 115b and an upper portion of the light-emitting element 120. A contact hole exposing the first electrode 124 and the second electrode of the light-emitting element 120 may be formed in the third planarization layer 115c. The first electrode 124 and the second electrode 125 of the light-emitting element 120 may be not covered with the third planarization layer 115c. The third planarization layer 115c may be partially disposed in an area between the first electrode 124 and the second electrode 125 to reduce a short circuit defect. A combination of the second planarization layer 115b and the third planarization layer 115c may be composed of a single layer or a multi-layer made of, for example, photoresist or an acryl-based organic material. However, embodiments of the present disclosure are not limited thereto. In one example, in the present disclosure, an example in which the second planarization layer 115b and the third planarization layer 115c are disposed is described. However, the planarization layer may be composed of a single layer. However, embodiments of the present disclosure are not limited thereto.

In one example, the third planarization layer 115c may cover only the light-emitting element 120 and an area adjacent to the light-emitting element 120. The third planarization layer 115c may be formed only in an area where the bank BB is not formed. The third planarization layer 115c may be disposed in an area of the sub-pixel SP surrounded with the bank BB and may be disposed in an island shape. Accordingly, the bank BB may be disposed on a portion of an upper surface of the second planarization layer 115b, and the third planarization layer 115c may be disposed on the other portion of the upper surface of the second planarization layer 115b.

The first connection electrode CE1 and the second connection electrode CE2 are disposed on the third planarization layer 115c. The first connection electrode CE1 may be an electrode that electrically connects the second electrode 125 of the light-emitting element 120 and the power line to each other. The first connection electrode CE1 may be electrically connected to the second electrode 125 of the light-emitting element 120 via a contact hole formed in the third planarization layer 115c.

The second connection electrode CE2 may be an electrode that electrically connects the first electrode 124 of the light-emitting element 120 to the driving transistor DT. The second connection electrode CE2 may be connected to the reflective layer RF of each of the plurality of sub-pixels SP via a contact hole extending through the third planarization layer 115c, the second planarization layer 115b, the adhesive layer AD, and the second passivation layer 114b. In this regard, since the reflective layer RF is connected to the source electrode SE of the driving transistor DT, the source electrode SE of the driving transistor DT may be electrically connected to the first electrode 124 of the light-emitting element 120 via the reflective layer RF and the second connection electrode CE2.

In one example, in the drawing, the first electrode 124, the second connection electrode CE2, and the reflective layer RF are shown as being electrically connected to the source electrode SE of the driving transistor DT. However, the first electrode 124, the second connection electrode CE2 and the reflective layer RF may be connected to the drain electrode DE of the driving transistor DT. However, embodiments of the present disclosure are not limited thereto.

The bank BB is disposed on a portion of the second planarization layer 115b not covered with the third planarization layer 115c and the first and second connection electrodes CE1 and CE2. The bank BB may be disposed to be spaced apart from the light-emitting element 120 by a certain distance. For example, the bank BB may be disposed on the second planarization layer 115b while being spaced from, by a certain distance, from the light-emitting element 120. The bank BB may cover a portion of the second connection electrode CE2 formed in the contact hole extending through the third planarization layer 115c and the second planarization layer 115b. The bank BB may be made of an opaque material to reduce color mixing between the plurality of sub-pixels SP. For example, the bank BB may be made of black resin. However, embodiments of the present disclosure are not limited thereto.

The protective layer 116 is disposed on the connection electrode and the bank BB. The protective layer 116 may act as a layer to protect the structure under the protective layer 116, and may be composed of a single layer or multiple layers made of transmissive epoxy, silicon oxide (SiOₓ), or silicon nitride (SiNₓ). However, embodiments of the present disclosure are not limited thereto.

Regarding the display device 100 according to one example embodiment of the present disclosure, the light-emitting element 120 from the donor may be easily transferred to the sub-pixel by positionally selectively controlling an adhesion force of the adhesive layer AD when manufacturing the display device 100. Hereinafter, a method for manufacturing the display device 100 according to one example embodiment of the present disclosure will be described with reference to FIGS. 4A to 4H.

FIGS. 4A to 4I illustrate a method for manufacturing a display device according to one example embodiment of the present disclosure. For convenience of illustration, FIGS. 4A to 4I only show a process of transferring the light-emitting element 120 to each of the plurality of first sub-pixels SP1 in FIG. 3A. Although not shown in the drawing, a process of transferring the light-emitting element 120 to the second sub-pixel SP2 and the third sub-pixel SP3 is substantially the same as the process of transferring the light-emitting element 120 to the first sub-pixel SP1. For convenience of illustration, a cured portion of the adhesive layer AD is shown in a non-hatched manner, and only an uncured portion thereof is shown in an hatched manner.

Referring to FIG. 4A, a wafer WF on which the plurality of light-emitting elements 120 has been formed is placed on a donor DN.

The wafer WF acts as a substrate on which the plurality of light-emitting elements 120 has been formed. After depositing a material such as gallium nitride (GaN) or indium gallium nitride (InGaN) that constitutes the plurality of light-emitting elements 120 on the wafer WF and growing a crystal layer thereof, the crystal layer may be cut into individual chips and the electrodes may be formed on the chips to form the plurality of light-emitting elements 120. The wafer WF may be made of sapphire, silicon carbide (SiC), gallium nitride (GaN), zinc oxide (ZnO), etc. However, embodiments of the present disclosure are not limited thereto.

The donor DN acts as a transfer member that is used to transfer the plurality of light-emitting elements 120 on the wafer WF to the display panel PN. The plurality of light-emitting elements 120 may be transferred onto the donor DN so as to be arranged to be spaced from each other by an equal spacing, and then, the plurality of light-emitting elements 120 may be transferred to the display panel PN at once. The donor DN may include a polymer resin having viscoelasticity so that the plurality of light-emitting elements 120 may be attached thereto.

After orienting the plurality of light-emitting elements 120 on the wafer WF so as to face the donor DN, some of the plurality of light-emitting elements 120 on the wafer WF may be selectively transferred to the donor DN. For example, laser LAS may be irradiated toward some light-emitting elements 120 of the plurality of light-emitting elements 120 on the wafer WF, and thus, some light-emitting elements 120 irradiated with the laser beam LAS may be detached from the wafer WF and may be adhered to the donor DN.

Referring to FIG. 4B together with FIG. 4A, the plurality of light-emitting elements 120 transferred onto the donor DN may be disposed in each of a plurality of first areas A1 of the donor DN. Each of the plurality of first areas A1 is an area corresponding to a column where the plurality of first sub-pixels SP1 are arranged. Each of the plurality of light-emitting elements 120 disposed in each of the plurality of first areas A1 may be transferred to the first sub-pixel SP1. The plurality of first areas A1 may be arranged so as to be spaced from each other by a spacing equal to the first length D1 as the spacing between adjacent ones of the plurality of pixels PX. A distance from one side edge of one first area A1 to one side edge of the first area A1 adjacent thereto may be the first length D1.

The donor DN includes the plurality of first areas A1, a plurality of second areas A2, and a plurality of third areas A3. Each of the plurality of second areas A2 is an area corresponding to a column where the plurality of second sub-pixels SP2 are arranged. Each of the plurality of third areas A3 is an area corresponding to a column where the plurality of third sub-pixels SP3 are arranged. Accordingly, when transferring each of the light-emitting elements 120 to each of the plurality of second sub-pixels SP2, the plurality of light-emitting elements 120 may be disposed in each of the plurality of second areas A2 of the donor DN. Likewise, when transferring each light-emitting element 120 to each of the plurality of third sub-pixels SP3, the plurality of light-emitting elements 120 may be disposed in each of the plurality of third areas A3 of the donor DN.

In one example, the plurality of light-emitting elements 120 transferred to each of the plurality of first areas A1 of the donor DN may be transferred to constitute a plurality of group 120G. Each of the plurality of groups 120G includes a plurality of light-emitting elements 120. When bonding the donor DN to the display panel PN, each of the plurality of groups 120G may correspond to one sub-pixel SP and an area adjacent to one sub-pixel SP. For example, when the group 120G is disposed in the first sub-pixel SP1 and an adjacent area thereto, one group 120G may partially overlap an area between one side edge of the first sub-pixel SP1 and one side edge of the second sub-pixel SP2 in the row direction and an area between one side edge of the first sub-pixel SP1 and one side edge of the neighboring first sub-pixel SP1 thereto in the column direction.

The plurality of light-emitting elements 120 constituting one group 120G may be arranged so as to be spaced from each other by a spacing smaller than a spacing between adjacent ones of the sub-pixels SP in each of the row and column directions. For example, a spacing between adjacent ones of the plurality of light-emitting elements 120 constituting one group 120G may be smaller than the second length D2 in the row direction and than the third length D3 in the column direction.

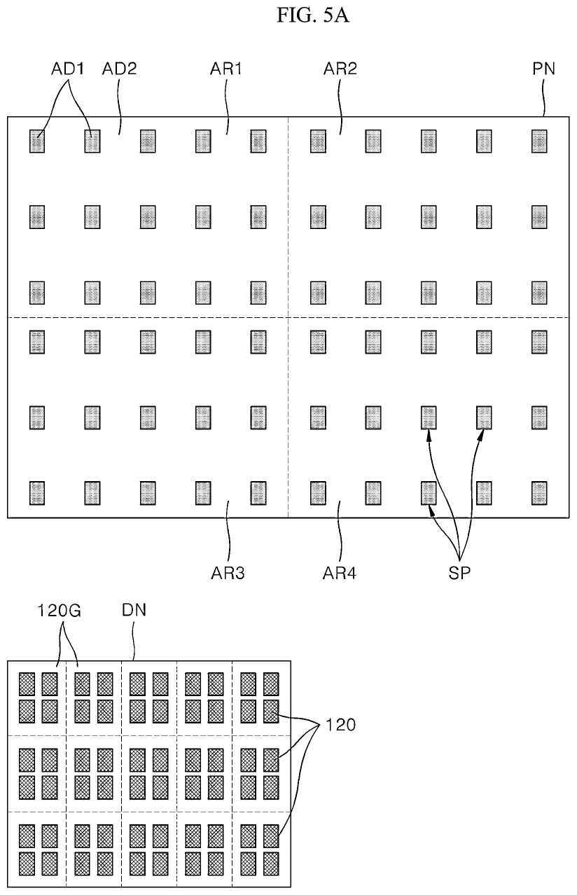

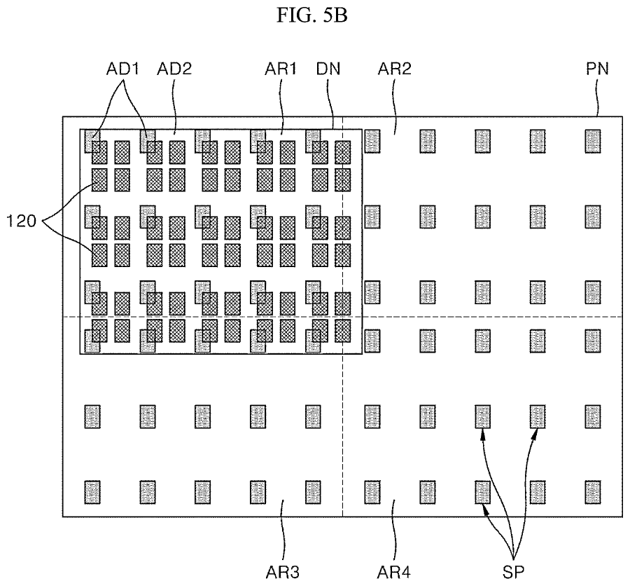

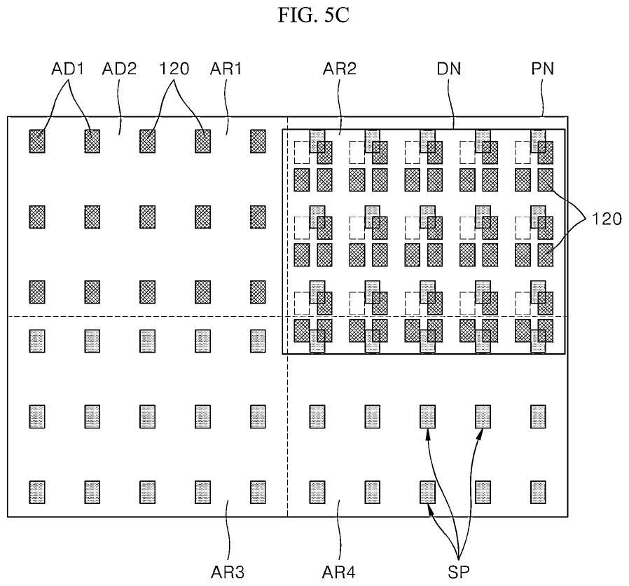

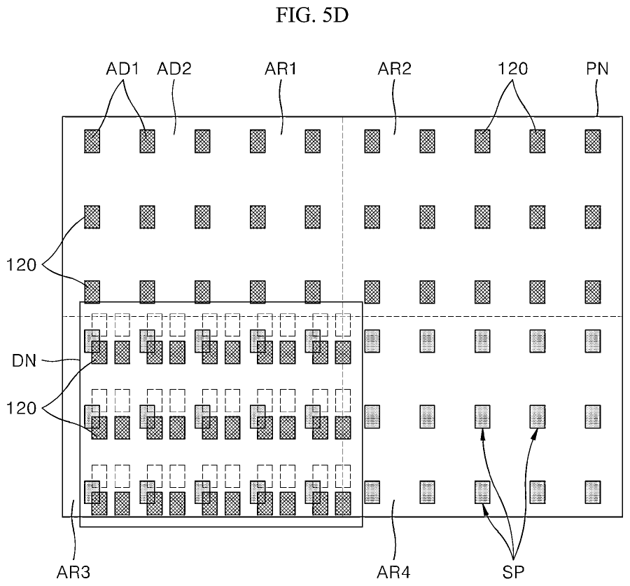

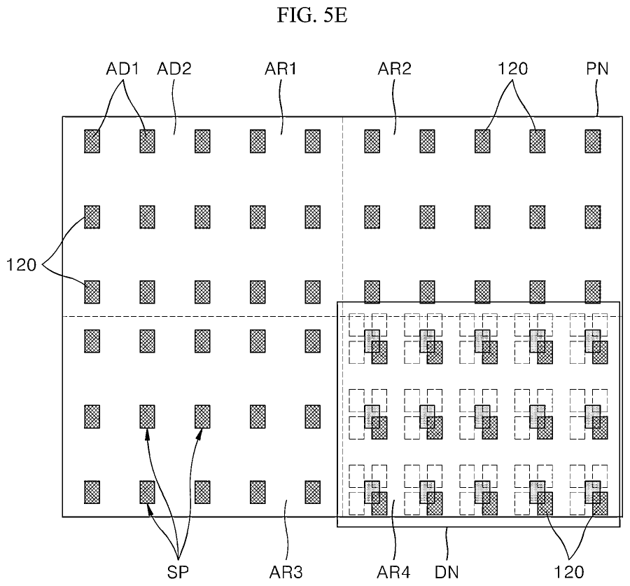

The number of light-emitting elements 120 included in each group 120G may vary depending on the number of times one donor DN is consecutively used in a transfer process. For example, when one donor DN is used n times consecutively in the transfer process of transferring the light-emitting elements 120 to the display panel PN, one group 120G may include n light-emitting elements 120. In each of a plurality of transfer processes, each of the plurality of light-emitting elements 120 included in one group 120G may be transferred to each of sub-pixels SP at different locations. Only the adhesive layer AD in an area to which each of the plurality of light-emitting elements 120 is to be transferred has selectively an adhesive force. Thus, only one of the plurality of light-emitting elements 120 included in one group 120G may be selectively transferred to one sub-pixel SP, and thus the transfer process may be performed multiple times in succession using one donor DN. A more detailed description thereof will be provided using FIG. 5A to FIG. 5E.

Next, referring to FIG. 4C and FIG. 4D, a mask MASK is disposed on the display panel PN having the adhesive layer AD formed thereon, and light LT is irradiated to the adhesive layer AD. The mask MASK may be placed to cover an area to which the plurality of light-emitting elements 120 are to be transferred, such that the light LT may be irradiated only to the remaining area to which the plurality of light-emitting elements 120 are not transferred. Accordingly, the adhesive layer AD may be composed of the plurality of first portions AD1 to which light LT has not been irradiated and a plurality of second portions AD2 to which light LT has been irradiated.

The plurality of first portions AD1 may respectively correspond to the plurality of sub-pixels SP, and each of the second portions AD2 may correspond to an area between adjacent ones of the sub-pixels SP. The second portion AD2 of the adhesive layer AD to which the light LT has been irradiated has been cured and does not have an adhesive force, while the plurality of first portions AD1 of the adhesive layer AD to which the light LT is not irradiated may have an adhesive force. Therefore, only the plurality of first portions AD1 corresponding to the plurality of sub-pixels SP in the adhesive layer AD formed on the front surface of the display panel PN may have an adhesive force, while the second portions AD2 do not have the adhesive force.

Next, referring to FIGS. 4E to 4H, the plurality of light-emitting elements 120 on the donor DN are transferred onto the adhesive layer AD of the display panel PN. Specifically, referring to FIG. 4E and FIG. 4F, the display panel PN having the adhesive layer AD formed thereon and the donor DN are aligned with each other. The donor DN is oriented so that the plurality of light-emitting elements 120 of the donor DN and the adhesive layer AD of the display panel PN face each other, and the display panel PN and the donor DN are bonded to each other. When bonding the donor DN and the display panel PN to each other, the adhesive layer AD of the display panel PN and the plurality of light-emitting elements 120 of the donor DN overlap each other as shown in FIG. 4F.

Referring to FIG. 4G and FIG. 4H together, the donor DN and the display panel PN are bonded to each other such that the light-emitting element 120 on the donor DN is transferred onto the adhesive layer AD, and then the donor DN may be detached from the display panel PN.

The light-emitting elements 120 respectively attached to the plurality of first portions AD1 of the adhesive layer AD may be detached from the donor DN and transferred to the display panel PN. However, the light-emitting element 120 in contact with the second portion AD2 of the adhesive layer AD from which the adhesive force has been removed by curing the second portion AD2 in the previous exposure process may remain in an attached state to the donor DN. Accordingly, only the light-emitting element 120 that is in contact with each of the plurality of first portions AD1 of the adhesive layer AD to which the light LT is not irradiated so as to maintain the adhesive force may be detached from the donor DN.

In this regard, the plurality of light-emitting elements 120 correspond only to the plurality of first areas A1 are disposed on the donor DN. Thus, the plurality of light-emitting elements 120 of the donor DN may only overlap each of the plurality of first areas A1 where the plurality of first sub-pixel SP1 of the display panel PN are arranged. Only one light-emitting element 120 among the plurality of light-emitting elements 120 included in one group 120G may be in contact with the first portion AD1 of the first area A1 and may be transferred to the display panel PN. The remaining light-emitting elements 120 may remain on the donor DN while being in contact with the second portions AD2. Since there is no light-emitting element 120 on an area of the donor DN corresponding to the plurality of second areas A2 and the plurality of third areas A3, the light-emitting element 120 is not transferred onto each of the plurality of first portions AD1 in the plurality of second areas A2 and the plurality of third areas A3. Accordingly, the plurality of light-emitting elements 120 may be respectively transferred to all of the plurality of first sub-pixels SP1 disposed in each off the plurality of first areas A1. The plurality of light-emitting elements 120 remaining in each of the plurality of groups 120G of the donor DN may be later transferred to the display panel PN in another transfer process.

Subsequently, the light-emitting element 120 may be transferred to each of the plurality of second sub-pixels SP2 disposed in each of the plurality of second areas A2. The light-emitting element 120 may be transferred to each of the plurality of third sub-pixels SP3 disposed in each of the plurality of third areas A3. This transfer process may be repeated. The light-emitting element 120 may be transferred to each of all of the plurality of sub-pixels SP. Specifically, as shown in FIG. 4A and FIG. 4B, the plurality of light-emitting elements 120 on the wafer WF may be transferred to each of the plurality of second areas A2 of the donor DN. As shown in FIG. 4E to FIG. 4H, the light-emitting elements 120 of the donor DN may be transferred to the plurality of first portions AD1 of the adhesive layer AD in each of the plurality of second areas A2, that is, to each of the second sub-pixels SP2. Then, the same process as the process in FIG. 4A and FIG. 4B, and FIG. 4E to FIG. 4H may be repeated such that the light-emitting element 120 may be transferred to each of the plurality of third sub-pixels SP3.

Lastly, referring to FIG. 4I, after completing the transfer process of the light-emitting elements 120 to all of the plurality of sub-pixels SP, the light LT may be irradiated to an entire area of the adhesive layer AD to cure the entirety thereof. The light LT may be irradiated to the entirety of the adhesive layer AD without a separate mask MASK, such that all of the plurality of first portions AD1 of the adhesive layer AD may be cured.

Although not shown in the drawing, after curing the entirety of the adhesive layer AD, the second planarization layer 115b, the third planarization layer 115c, the bank BB, the first connection electrode CE1, the second connection electrode CE2, and the protective layer 116 may be formed on the adhesive layer AD. In this way, the manufacturing process of the display device 100 has been completed.

Therefore, in the display device 100 and the method for manufacturing the display device 100 according to one example embodiment of the present disclosure, while the plurality of light-emitting elements 120 may be disposed on the donor DN and may be arranged so as to be spaced from each other by a spacing smaller than a spacing between adjacent ones of the plurality of sub-pixels SP, only the plurality of first portions AD1 corresponding to the plurality of sub-pixels SP in the adhesive layer AD of the display panel PN have the adhesive force. In this state, the transfer process may be performed. Accordingly, only the light-emitting elements 120 respectively overlapping the plurality of sub-pixels SP among the plurality of light-emitting elements 120 on the donor DN may be selectively transferred to the display panel PN. Thus, a transfer defect in which the light-emitting element 120 is transferred to an area other than the plurality of sub-pixels SP in the display panel PN may be minimized.

Further, in the method for manufacturing the display device 100 according to one example embodiment of the present disclosure, a transfer process time may be shortened by consecutively performing the transfer process multiple times using one donor DN. This will be described below with referring to FIGS. 5A to 5E.

FIGS. 5A to 5E illustrate a method for manufacturing a display device according to one example embodiment of the present disclosure. FIGS. 5A to 5E illustrate a process of transferring the plurality of light-emitting elements 120 on the donor DN to the display panel PN when the display panel PN has a larger size than that of the donor DN.

Referring to FIG. 5A, the display panel PN may have a larger size than that of the donor DN. For example, the size of the display panel PN is about 4 times of the size of the donor DN. In this case, in order to transfer the light-emitting elements 120 to an entirety of the display panel PN, 4 donors DN or 4 transfer processes may be required. However, in a method for manufacturing the display device 100 according to one example embodiment of the present disclosure, the adhesive layer AD may have the adhesive force only in an area thereof corresponding to each of the plurality of sub-pixels SP. Thus, only some of the plurality of light-emitting elements 120 disposed on one donor DN may be selectively transferred onto the display panel PN, and the transfer process may be performed multiple times using one donor DN.

Hereinafter, for convenience of description, the description will be made based on an example in which the size of the display panel PN is about 4 times of the size of the donor DN. However, a size ratio of the donor DN and the display panel PN is merely an example. Embodiments of the present disclosure are not limited thereto.

In this case, when the light-emitting elements 120 have been transferred to all of the plurality of sub-pixels SP of the display panel PN in four times of transfer processes, the display panel PN may be divided into four areas. One time transfer process is performed per each of the four areas. The four areas may include, for example, a first transfer target area AR1, a second transfer target area AR2, a third transfer target area AR3, and a fourth transfer target area AR4. The light-emitting elements 120 may be transferred to one of the first transfer target area AR1, the second transfer target area AR2, the third transfer target area AR3, and the fourth transfer target area AR4 in one transfer process.

Before transferring the light-emitting element 120 from the donor DN to the display panel PN, the mask MASK may be disposed on the adhesive layer AD formed on the entirety of the display panel PN and the light LT may be irradiated thereto such that the adhesive layer AD may be divided into the plurality of first portions AD1 corresponding to the plurality of sub-pixels SP and not subjected to the light irradiation and having the adhesive force and the second portions AD2 subjected to the light irradiation and not having the adhesive force. Accordingly, the adhesive layer AD may be formed on the entirety of the display panel PN, while only the area of the adhesive layer AD corresponding to each of the plurality of sub-pixels SP may have the adhesive force.

The plurality of light-emitting elements 120 to be transferred to all of the first transfer target area AR1, the second transfer target area AR2, the third transfer target area AR3, and the fourth transfer target area AR4 may be disposed on the donor DN. For example, when 15 light-emitting elements 120 are respectively transferred to 15 sub-pixels SP in each of the first transfer target area AR1, the second transfer target area AR2, the third transfer target area AR3, and the fourth transfer target area AR4, 15 groups 120G, each including four light-emitting elements 120 to be respectively used in four transfer processes, that is, 60 light-emitting elements 120 may be disposed on the donor DN.

Referring to FIG. 5B, the plurality of light-emitting elements 120 on the donor DN may be transferred to the first transfer target area of the display panel PN by bonding the donor DN on the first transfer target area AR1 of the display panel PN. In this regard, all of the plurality of light-emitting elements 120 on the donor DN may be in contact with the adhesive layer AD of the first transfer target area AR1 or only the light-emitting elements 120 in contact with the plurality of first portions AD1 having the adhesive force may be selectively transferred to the first transfer target area AR1, while the light-emitting elements 120 in contact with the second portions AD2 thereof remain on the donor DN.

Next, referring to FIG. 5C, the donor DN is bonded onto the second transfer target area AR2. In this case, the donor DN may be shifted such that one of the plurality of light-emitting elements 120 in each of the plurality of groups 120G on the donor DN contacts one of the plurality of first portions AD1 of the adhesive layer AD, and the donor DN may be bonded to the second transfer target area AR2. The donor DN and the display panel PN may be aligned with each other so that one of the plurality of light-emitting elements 120 in each group 120G overlaps the first portion AD1 of the adhesive layer AD, and then, the donor DN may be bonded to the display panel PN. Accordingly, the plurality of light-emitting elements 120 of the donor DN may be in contact with the plurality of first portions AD1, respectively. Thus, the light-emitting elements 120 may be respectively transferred to the plurality of sub-pixels SP of the second transfer target area AR2. The remaining light-emitting elements 120 in contact with the second portions AD2 of the second transfer target area AR2 may remain in the attached state to the donor DN.

Referring to FIG. 5D, as in the transfer process to the second transfer target area AR2, the donor DN may be shifted and bonded to the third transfer target area AR3. Specifically, the donor DN may be aligned with the display panel so that one of the plurality of light-emitting elements 120 in each group 120G corresponds to the first portion AD1 of the adhesive layer AD, and then, the donor DN may be bonded onto the third transfer target area AR3. Accordingly, one of the light-emitting elements 120 of each group 120G may be transferred to the corresponding one of the plurality of sub-pixels SP of the third transfer target area AR3.

Finally, referring to FIG. 5E, the donor DN may be aligned such that the remaining light-emitting elements 120 in each of the plurality of groups 120G on the donor DN correspond to the remaining first portion AD1 of the adhesive layer AD. Then, the donor may be bonded onto the fourth transfer target area AR4. Therefore, all of the plurality of light-emitting elements 120 disposed on the donor DN may be transferred to the display panel PN.

For example, in order to transfer the light-emitting elements on the donor to the plurality of sub-pixels while the entirety of the adhesive layer has the adhesive force, the light-emitting elements should have only an arrangement corresponding to an arrangement of the plurality of sub-pixels on the donor. When the light-emitting element is located in an area that does not correspond to each of the plurality of sub-pixels, a defect may occur in which the light-emitting element is transferred to the area other than the area corresponding to the sub-pixel during the bonding process between the donor and the display panel. Accordingly, when the display panel has a size larger than that of the donor, the display device may be manufactured using a plurality of donors on which the light-emitting elements are disposed so as to have the arrangement corresponding to the arrangement of the plurality of sub-pixels. However, as the plurality of donors are used, the light-emitting elements on the wafer should be selectively transferred to each of the donors. Thus, the number of transfer processes may increase, and thus the transfer process time may increase.

However, in the display device 100 and the method for manufacturing the display device 100 according to one example embodiment of the present disclosure, the plurality of light-emitting elements 120 are transferred onto the donor DN at once. Then, only the area of the adhesive layer AD corresponding to each of the plurality of sub-pixels SP of the display panel PN has the adhesive force. Thus, only some of the plurality of light-emitting elements 120 on the donor DN may be selectively transferred to the sub-pixels SP. Therefore, the light-emitting elements 120 may be transferred to the plurality of areas of the display panel PN using one donor DN, thereby reducing the number of donors DN required in an entire transfer process. Therefore, the number of processes and the process time for transferring the light-emitting elements 120 from the wafer WF to the donor DN may be reduced.

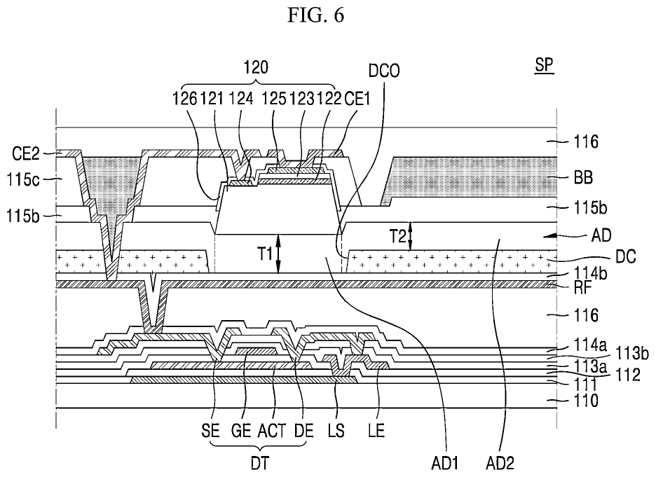

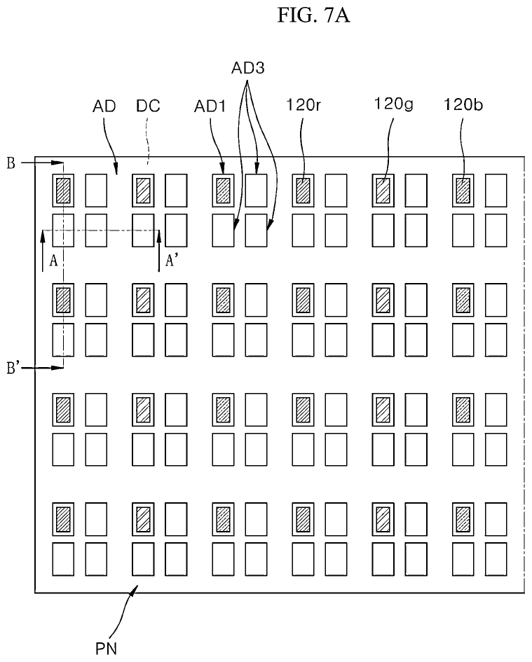

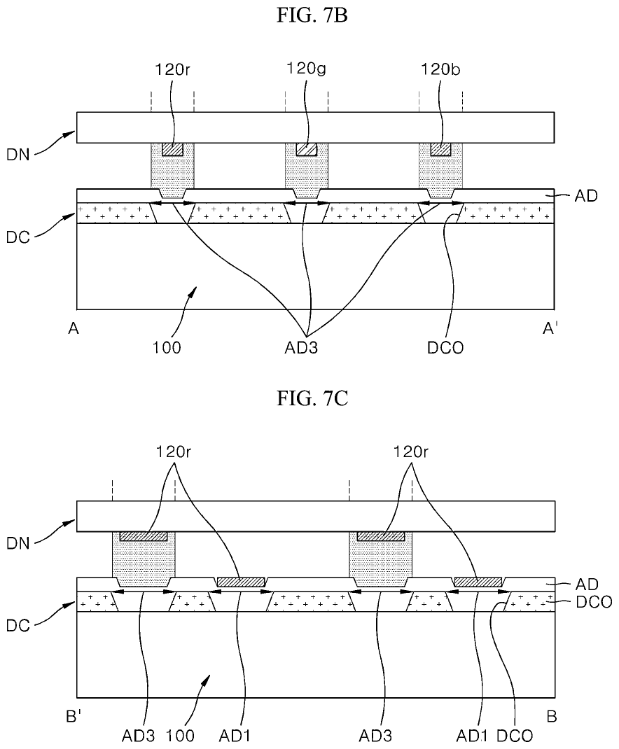

FIG. 6 is a cross-sectional view of a display device according to another example embodiment of the present disclosure. FIG. 7A is a top view of a display device according to another example embodiment of the present disclosure. FIG. 7B is a cross-sectional view of an area A-A′ in FIG. 7A. FIG. 7C is a cross-sectional view of an area B-B′ in FIG. 7A.

A display device 600 in FIG. 6 is different from the display device 100 in FIGS. 1 to 5E only in relation to a step formation layer DC and the adhesive layer AD, and other components thereof are substantially the same as each other. Thus, duplicate descriptions thereof are omitted. For convenience of illustration, FIG. 7B and FIG. 7C show only the substrate 110, the step formation layer DC, and the adhesive layer AD among the components of the display panel PN.

Referring to FIG. 6 and FIG. 7A, the step formation layer DC may be disposed on the substrate 110 of the display device 600 according to another example embodiment of the present disclosure. The step formation layer DC may overlap the light-emitting element 120 or have an opening DCO defined therein in an area adjacent to the light-emitting element 120. The adhesive layer AD may be disposed on the step formation layer DC. In this regard, due to the opening DCO formed in the step formation layer DC, the adhesive layer AD may be composed of a first portion AD1 with a relatively larger first thickness T1 and a second portion AD2 having a relatively smaller second thickness T2.

As the first portion AD1 of the adhesive layer AD is formed to fill the opening DCO formed in the step formation layer DC, the first portion may have a relatively larger first thickness T1. The second portion AD2 of the adhesive layer AD is formed to cover an upper surface of a portion of the step formation layer DC disposed between the adjacent openings DCO, and thus has the second thickness T2 relatively smaller than the first thickness T1. A vertical level of a top surface of the first portion AD1 may be lower than a vertical level of a top surface of the second portion AD2. The step formation layer DC may be made of an organic material such as acryl-based resin or polyimide, or an inorganic material such as SiOₓ or SiON. However, embodiments of the present disclosure are not limited thereto.

Each of the plurality of first portions AD1 of the adhesive layer AD respectively in contact with the plurality of light-emitting elements 120 may be disposed in the opening DCO. Additionally, the second portion AD2 of the adhesive layer AD to which each of the plurality of light-emitting elements 120 is not transferred may be disposed in an area that does not overlap with the opening DCO. In an example embodiment according to the present disclosure, the plurality of first portions AD1 of the adhesive layer AD may be classified into a transfer target area to which the light-emitting element 120 is transferred and a non-transfer target area to which the light-emitting element 120 is not transferred. In this regard, the non-transfer target area may be referred to as a non-adhering area. In this case, the adhesive layer AD may have different thicknesses in the transfer target area and the non-transfer target area. This will be further described in FIG. 7A to FIG. 7C below.

Referring to FIG. 6 and FIG. 7A, in the display device 600 according to another example embodiment of the present disclosure, the adhesive layer may further have the non-adhering area AD3 as an area to which the light-emitting element 120 is not transferred but overlaps with the opening DCO. Accordingly, the adhesive layer AD may include the transfer target area to which the light-emitting element 120 is transferred and the non-transfer target area to which the light-emitting element 120 is not transferred. In this regard, the transfer target area may be referred to as an adhering area, and the non-transfer target area may also be referred to as a non-adhering area. The non-adhering area AD3 overlaps with the light-emitting element 120 that is not transferred to the display panel PN during the process of transferring the light-emitting elements 120 from the donor DN to the display panel PN.

A vertical level of a top surface of the adhering area of the first portion AD1 may be equal to a vertical level of a top surface of the non-adhering area AD3. However, embodiments of the present disclosure are not limited thereto. In the transfer process, the remaining light-emitting element 120 other than the light-emitting elements 120r, 120g, and 120b transferred to the first portion AD1 among the plurality of light-emitting elements 120 attached to the donor should not be transferred to the display panel PN. For this purpose, the light LT may be irradiated to the non-adhering area AD3 using a mask MASK. Accordingly, the non-adhering area AD3 of the adhesive layer AD to which the light LT is irradiated is cured and does not have the adhesive force, and the first portion AD1 to which the light LT is not irradiated may have the adhesive force. Therefore, in the adhesive layer AD formed on the front surface of the display panel PN, the plurality of first portions AD1 corresponding to the plurality of sub-pixels SP have the adhesive force. The non-adhering area AD3 to which the light-emitting element 120 is not transferred does not have the adhesive force. The non-adhering area AD3 may be square or circular in a plan view. However, embodiments of the present disclosure are not limited thereto.

In one or more examples, the mask MASK may include openings and opaque regions. In an example, the first portions AD1 overlap the mask, and the non-adhering areas AD3 do not overlap the mask but are subjected to the irradiated light. For example, the first portions AD1 overlap the opaque regions of the mask MASK so that the first portions AD1 are not irradiated by the light LT. On the other hand, the non-adhering areas AD3 do not overlap the opaque regions of the mask MASK so that that the non-adhering areas AD3 are irradiated by the light LT.

Afterwards, when the donor DN is bonded to the display panel PN, the light-emitting elements 120r, 120g, and 120b are respectively attached only to the plurality of first portions AD1 of the adhesive layer AD, while the light-emitting element 120 in contact with the non-adhering area AD3 may remain in the attached state to the donor DN.

A thickness of each of the plurality of first portions AD1 of the adhesive layer AD to which the plurality of light-emitting elements 120 are attached is larger than that of the second portion AD2 of the adhesive layer AD. Thus, the adhesion force of the first portion AD1 may be further improved. The adhesion force of the adhesive layer AD may be affected by factors such as a thickness of the adhesive layer AD and a detachment speed between the donor DN and the display panel PN. For example, as the thickness of the adhesive layer AD increases, the adhesive force of the adhesive layer AD may increase. Therefore, each of the plurality of first portions AD1 of the adhesive layer AD in contact with the plurality of light-emitting elements 120 is thicker than that of the remaining portion of the adhesive layer AD, such that the plurality of light-emitting elements 120 may be fixed more stably to the display panel PN. The thickness of the adhesive layer AD in the non-adhering area AD3 may be equal to the thickness of the adhesive layer AD in the first portion AD1 as the adhering area. This, the adhesive force of the non-adhering area AD3 may be equal to that of the first portion AD1 as the adhering area. However, when the step formation layer DC is disposed under the non-adhering area AD3, so that a vertical level of a top surface of the adhesive layer AD in the non-adhering area AD3 is equal to that of a top surface of the second portion AD2, a problem may arise. For example, in the process of transferring the light-emitting element 120 from the donor DN to the display panel PN under application of a pressure, an upper portion of the adhesive layer AD in the non-adhering area AD3 which has lost its adhesive force due to the curing under the irradiation of the light LT thereto is broken, such that a lower portion of the adhesive layer AD which has the adhesive force is exposed, such that the light-emitting element that should not be transferred may be transferred to the non-adhering area AD3. To prevent this situation, in the display device 600 according to another example embodiment of the present disclosure, the vertical level of the top surface of the adhesive layer AD3 in the non-adhering area AD3 is lower than the vertical level of the top surface of the second portion AD2. Thus, the upper portion thereof may be prevented from being broken due to the pressure. Further, the adhesion of the adhesive layer AD in the non-adhering area AD3 may be removed by irradiating the light LT thereto. An area size of the non-adhering area AD3 may be larger, smaller, or equal to an area size of the opening DCO.

FIG. 7B is a cross-sectional view of an area A-A′ in FIG. 7A. FIG. 7C is a cross-sectional view of an area B-B′ in FIG. 7A.

Referring to FIG. 7B, in the process of transferring the light-emitting element 120 from the donor DN to the display panel PN, the light-emitting element 120 is not transferred to the non-adhering area AD3 disposed in the A-A′ area but remains on the donor DN. Referring to FIG. 7C, in the process of transferring the light-emitting element 120 from the donor DN to the display panel PN, the light-emitting element 120 is not transferred to the non-adhering area AD3 disposed in the B-B′ area but remains on the donor DN. In another embodiment of the present disclosure, each of the plurality of first portions AD1 and each of the plurality of non-adhering areas AD3 of the adhesive layer AD may have different area sizes. For example, a first area size of each of the plurality of non-adhering areas AD3 of the adhesive layer AD may be larger than a second area size of each of the first portions AD1 of the adhesive layer AD. Accordingly, the adhesive layer AD may be formed so that a thickness of the first portion AD1 is equal to or larger than the thickness thereof in the non-adhering area AD3.

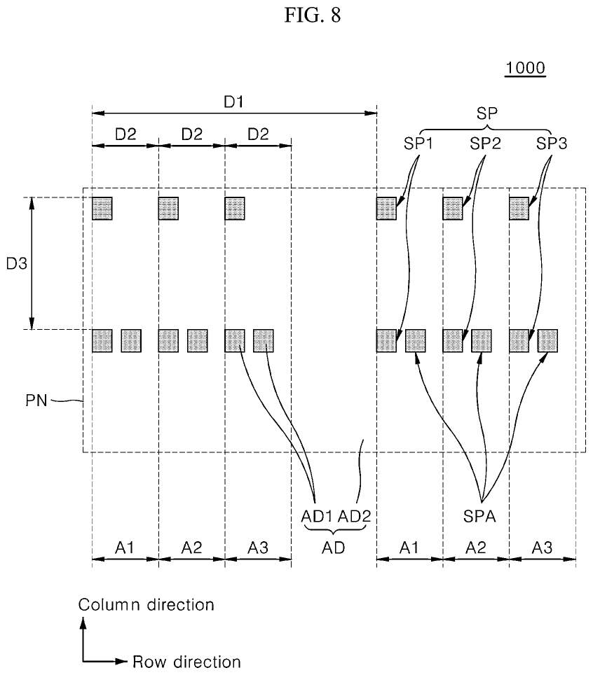

FIG. 8 is a top view of a display device according to still another example embodiment of the present disclosure. The display device 1000 in FIG. 8 differs from the display device 100 in FIGS. 1 to 5E only in relation to the plurality of sub-pixels SP and the adhesive layer AD. Other components thereof are substantially the same as each other. Thus, duplicate descriptions thereof are omitted. For convenience of illustration, FIG. 8 shows only the adhesive layer AD and the plurality of sub-pixels SP.

Referring to FIG. 8, an additional sub-pixel SPA is further disposed on the substrate 110. The additional sub-pixel SPA is a component for repairing a defective sub-pixel SP by additionally transferring the light-emitting element 120 to the additional sub-pixel SPA when the transfer process of transferring the light-emitting element 120 is defective. The additional sub-pixel SPA may be disposed adjacent to some sub-pixels SP among the plurality of sub-pixels SP. For example, the additional sub-pixel SPA may be disposed between adjacent ones of the plurality of sub-pixels SP in each of some rows among the plurality of rows. However, the arrangement of the additional sub-pixels SPA shown in FIG. 8 is illustrative and is not limited thereto.

After bonding the donor DN and display panel PN to each other to transfer the light-emitting elements 120 to the plurality of sub-pixels SP, whether there is a sub-pixel SP in which a transfer failure occurs may be identified. When the light-emitting element 120 is not transferred to the first sub-pixel SP1 among the plurality of sub-pixels SP, or when the light-emitting element 120 is transferred to a position out of a target position thereof, the light-emitting element 120 may be additionally transferred to the additional sub-pixel SPA adjacent to the first sub-pixel SP1 such that the defective sub-pixel SP is replaced.

In order to transfer the light-emitting element 120 to the additional sub-pixel SPA, a portion of the adhesive layer AD corresponding to the additional sub-pixel SPA may also be formed as a first portion AD1. For example, before transferring the plurality of light-emitting elements 120 to the display panel PN, the mask MASK that covers the plurality of sub-pixels SP and the additional sub-pixel SPA may be placed, and then, the adhesion force of the non-adhering area AD3 (see FIG. 7A) of the adhesive layer AD may be removed by irradiating light LT thereto. The plurality of first portions AD1 to which the light LT is not irradiated, that is, the plurality of portions of the adhesive layer AD overlapping the plurality of sub-pixels SP and the plurality of additional sub-pixel SPA may still have the adhesive force. Therefore, after detecting the transfer failure in the display panel PN, the light-emitting element 120 may be transferred onto the first portion AD1 with the adhesive force corresponding to the additional sub-pixel SPA such that the defective sub-pixel SP may be repaired. After the repair has been completed, the entirety of the adhesive layer AD may be cured by irradiating the light LT again to the plurality of first portions AD1, the non-adhering areas AD3, and the second areas AD2.

Therefore, in the display device 1000 according to still another example embodiment of the present disclosure, when the additional sub-pixel SPA for repair is formed, the first portion AD1 of the adhesive layer AD corresponding to the additional sub-pixel SPA may be further formed. The light-emitting element 120 may be transferred to the display panel PN via the first portion AD1 in an additional transfer process. Accordingly, the adhesive layer AD may be designed into various structures in consideration of the repair process, etc.

Various examples and aspects of the present disclosure are described below. These are provided as examples, and do not limit the scope of the present disclosure.

One or more aspects of the present disclosure provide a display device comprising: a substrate on which pixels are defined, each pixel including a plurality of sub-pixels; a step formation layer disposed on the substrate; an adhesive layer disposed on the step formation layer; and a plurality of light-emitting elements respectively disposed in the plurality of sub-pixels, and disposed on the adhesive layer, wherein the adhesive layer includes: a plurality of first portions respectively overlapping the plurality of light-emitting elements, a plurality of non-adhering areas respectively disposed adjacent to the plurality of first portions; and a second portion other than the plurality of first portions and the plurality of non-adhering areas.

According to some features of the display device, the step formation layer has a first plurality of openings and a second plurality of openings defined in the step formation layer; each of the first plurality of openings overlaps with a respective one of the plurality of first portions; and each of the second plurality of openings overlaps with a respective one of the plurality of non-adhering areas.

According to some features of the display device, a thickness of each of the plurality of first portions of the adhesive layer is greater than a thickness of the second portion of the adhesive layer.

According to some features of the display device, a thickness of each of the plurality of non-adhering areas of the adhesive layer is equal to a thickness of an adjacent one of the plurality of first portions of the adhesive layer.

According to some features of the display device, the plurality of light-emitting elements do not overlap any of the plurality of non-adhering areas of the adhesive layer.

According to some features of the display device, each of the plurality of non-adhering areas of the adhesive layer includes a portion resulting from light irradiation and curing.

According to some features of the display device, an adhesive force of each of the plurality of first portions of the adhesive layer is greater than an adhesive force of each of the plurality of non-adhering areas of the adhesive layer.

According to some features of the display device, an area size of each of the plurality of non-adhering areas of the adhesive layer is greater than an area size of each of the plurality of first portions of the adhesive layer, and wherein a thickness of one or each of the plurality of first portions of the adhesive layer is equal to or larger than a thickness of each of the plurality of non-adhering areas of the adhesive layer.

According to some features of the display device, a vertical level of a top surface of each of the plurality of non-adhering areas of the adhesive layer is lower than a vertical level of a top surface of the second portion of the adhesive layer.

According to some features of the display device, a vertical level of a top surface of each of the plurality of first portions of the adhesive layer is lower than a vertical level of a top surface of the second portion of the adhesive layer.

One or more aspects of the present disclosure provide a method for manufacturing a display device including transferring a plurality of light-emitting elements on a wafer to a donor; disposing a step formation layer on a substrate of a display panel; patterning the step formation layer to form a first plurality of openings and a second plurality of openings defined in the step formation layer; disposing an adhesive layer on the step formation layer; disposing a mask on the adhesive layer and irradiating light to the adhesive layer; and transferring the plurality of light-emitting elements on the donor to the display panel, wherein the adhesive layer includes a plurality of first portions overlapping the mask, and a plurality of non-adhering areas not overlapping with the mask and subjected to the irradiated light, wherein each of the first plurality of openings overlaps with a respective one of the plurality of first portions, wherein each of the second plurality of openings overlaps with a respective one of the plurality of non-adhering areas, and wherein only light-emitting elements respectively in contact with the plurality of first portions among the plurality of light-emitting elements are transferred to the display panel.

According to some features of the method, disposing the mask on the adhesive layer and irradiating the light to the adhesive layer includes blocking light from traveling to the plurality of first portions so that the plurality of first portions are not cured, and irradiating the light to the plurality of non-adhering areas to cure the plurality of non-adhering areas.

According to some features of the method, the method further comprises, after transferring the plurality of light-emitting elements to the display panel, irradiating light to the adhesive layer to cure an entirety of the adhesive layer.

According to some features of the method, a thickness of each of the plurality of first portions is equal to a thickness of each of the non-adhering areas, and is smaller than a thickness of a second portion, wherein the second portion is a remaining area of the adhesive layer other than the plurality of first portions and the plurality of non-adhering areas, and wherein an adhesive force of each of the plurality of first portions is greater than an adhesive force of the second portion.

According to some features of the method, the display panel includes a plurality of sub-pixels, wherein the plurality of first portions of the adhesive layer correspond to the plurality of sub-pixels, respectively.

According to some features of the method, the plurality of light-emitting elements transferred from the wafer to the donor are grouped into a plurality of groups, wherein in transferring the plurality of light-emitting elements on the donor to the display panel, each of the plurality of groups is positioned to overlap a respective one of the plurality of sub-pixels and an area adjacent to the respective one of the plurality of sub-pixels.

According to some features of the method, each of at least one of a plurality of light-emitting elements included in each of the plurality of groups overlaps a corresponding one of the plurality of first portions, while each of remaining ones of the plurality of light-emitting elements included in each of the plurality of groups overlaps a corresponding one of the plurality of non-adhering areas.

According to some features of the method, the display panel further includes an additional sub-pixel disposed between adjacent ones of the plurality of sub-pixels, and wherein one of the plurality of first portions of the adhesive layer corresponds to the additional sub-pixel.

According to some features of the method, the method further comprises: after transferring the plurality of light-emitting elements to the display panel, detecting a transfer failure in transferring the plurality of light-emitting elements; transferring a light-emitting element to the additional sub-pixel adjacent to a sub-pixel in which the transfer failure has occurred; and curing an entirety of the adhesive layer.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended for illustrating rather than limit the technical idea of the present disclosure, and the scope of the technical idea of the present disclosure is not limited by these embodiments. Therefore, it should be understood that the embodiments described above are not restrictive but illustrative in all respects. The scope of protection of the present disclosure should be construed based on the following claims, and all technical features within the scope of equivalents thereof should be construed as being included within the scope of the present disclosure.

What is claimed is:

1. A display device, comprising:
a substrate on which pixels are defined, each pixel including a plurality of sub-pixels;
a step formation layer disposed on the substrate;
an adhesive layer disposed on the step formation layer; and
a plurality of light-emitting elements respectively disposed in the plurality of sub-pixels, and disposed on the adhesive layer,
wherein the adhesive layer includes:
a plurality of first portions respectively overlapping the plurality of light-emitting elements;
a plurality of non-adhering areas respectively disposed adjacent to the plurality of first portions; and
a second portion other than the plurality of first portions and the plurality of non-adhering areas.

2. The display device of claim 1, wherein:
the step formation layer has a first plurality of openings and a second plurality of openings defined in the step formation layer;
each of the first plurality of openings overlaps with a respective one of the plurality of first portions; and
each of the second plurality of openings overlaps with a respective one of the plurality of non-adhering areas.

3. The display device of claim 2, wherein a thickness of each of the plurality of first portions of the adhesive layer is greater than a thickness of the second portion of the adhesive layer.

4. The display device of claim 3, wherein a thickness of each of the plurality of non-adhering areas of the adhesive layer is equal to a thickness of an adjacent one of the plurality of first portions of the adhesive layer.

5. The display device of claim 4, wherein the plurality of light-emitting elements do not overlap any of the plurality of non-adhering areas of the adhesive layer.

6. The display device of claim 4, wherein each of the plurality of non-adhering areas of the adhesive layer includes a portion resulting from light irradiation and curing.

7. The display device of claim 4, wherein an adhesive force of each of the plurality of first portions of the adhesive layer is greater than an adhesive force of each of the plurality of non-adhering areas of the adhesive layer.

8. The display device of claim 3, wherein an area size of each of the plurality of non-adhering areas of the adhesive layer is greater than an area size of each of the plurality of first portions of the adhesive layer, and
wherein a thickness of one of the plurality of first portions of the adhesive layer is equal to or larger than a thickness of each of the plurality of non-adhering areas of the adhesive layer.

9. The display device of claim 4, wherein a vertical level of a top surface of each of the plurality of non-adhering areas of the adhesive layer is lower than a vertical level of a top surface of the second portion of the adhesive layer.

10. The display device of claim 3, wherein a vertical level of a top surface of each of the plurality of first portions of the adhesive layer is lower than a vertical level of a top surface of the second portion of the adhesive layer.

11. A method for manufacturing a display device, the method comprising:
transferring a plurality of light-emitting elements on a wafer to a donor;
disposing a step formation layer on a substrate of a display panel;
patterning the step formation layer to form a first plurality of openings and a second plurality of openings defined in the step formation layer;
disposing an adhesive layer on the step formation layer;
disposing a mask on the adhesive layer and irradiating light to the adhesive layer; and
transferring the plurality of light-emitting elements on the donor to the display panel,
wherein the adhesive layer includes a plurality of first portions overlapping the mask, and a plurality of non-adhering areas not overlapping with the mask and subjected to the irradiated light,
wherein each of the first plurality of openings overlaps with a respective one of the plurality of first portions,
wherein each of the second plurality of openings overlaps with a respective one of the plurality of non-adhering areas, and
wherein only light-emitting elements respectively in contact with the plurality of first portions among the plurality of light-emitting elements are transferred to the display panel.

12. The method of claim 11, wherein disposing the mask on the adhesive layer and irradiating the light to the adhesive layer includes blocking light from traveling to the plurality of first portions so that the plurality of first portions are not cured, and irradiating the light to the plurality of non-adhering areas to cure the plurality of non-adhering areas.

13. The method of claim 12, wherein the method further comprises, after transferring the plurality of light-emitting elements to the display panel, irradiating light to the adhesive layer to cure an entirety of the adhesive layer.

14. The method of claim 12, wherein a thickness of each of the plurality of first portions is equal to a thickness of each of the non-adhering areas, and is smaller than a thickness of a second portion,
wherein the second portion is a remaining area of the adhesive layer other than the plurality of first portions and the plurality of non-adhering areas, and
wherein an adhesive force of each of the plurality of first portions is greater than an adhesive force of the second portion.

15. The method of claim 11, wherein the display panel includes a plurality of sub-pixels, and
wherein the plurality of first portions of the adhesive layer correspond to the plurality of sub-pixels, respectively.

16. The method of claim 15, wherein the plurality of light-emitting elements transferred from the wafer to the donor are grouped into a plurality of groups, and
wherein in transferring the plurality of light-emitting elements on the donor to the display panel, each of the plurality of groups is positioned to overlap a respective one of the plurality of sub-pixels and an area adjacent to the respective one of the plurality of sub-pixels.

17. The method of claim 16, wherein each of at least one of a plurality of light-emitting elements included in each of the plurality of groups overlaps a corresponding one of the plurality of first portions, while each of remaining ones of the plurality of light-emitting elements included in each of the plurality of groups overlaps a corresponding one of the plurality of non-adhering areas.

18. The method of claim 15, wherein the display panel further includes an additional sub-pixel disposed between adjacent ones of the plurality of sub-pixels, and
wherein one of the plurality of first portions of the adhesive layer corresponds to the additional sub-pixel.

19. The method of claim 18, wherein the method further comprises:
after transferring the plurality of light-emitting elements to the display panel, detecting a transfer failure in transferring the plurality of light-emitting elements;
transferring a light-emitting element to the additional sub-pixel adjacent to a sub-pixel in which the transfer failure has occurred; and
curing an entirety of the adhesive layer.
